(19) United States
(12) Patent Application Publication
(10) Pub. No.: US 2025/0218909 A1
(43) Pub. Date: Jul. 3, 2025

(54) ENVIRONMENTAL SEALING FOR ELECTRONICS CHIP PACKAGE SOCKETS

(71) Applicant: Intel Corporation, Santa Clara, CA (US)

(72) Inventors: Donald Tiendung TRAN, Phoenix, AZ (US); Andres RAMIREZ MACIAS, Zapopan (MX); Srikant NEKKANTY, Chandler, AZ (US); Jorge Enrique CONTRERAS PEREZ, Guadalajara (MX)

(21) Appl. No.: 18/398,766

(22) Filed: Dec. 28, 2023

(51) Int. Cl. H01L 23/498; H01L 23/10; H01L 23/367; H05K 7/10

(52) U.S. Cl. CPC H01L 23/49811; H01L 23/10; H01L 23/367; H05K 7/1061; H01L 23/49827

(57) ABSTRACT

Embodiments disclosed herein include socketing apparatuses with environmental sealing options. In an embodiment, such an apparatus comprises a first substrate, and a second substrate over the first substrate. In an embodiment, a socket structure is provided between the first substrate and the second substrate, where the socket structure comprises a plurality of electrical interconnects between the first substrate and the second substrate. In an embodiment, a die is over the second substrate, and a third substrate is over the die. In an embodiment, a ring is around the socket structure, and the ring is coupled to the first substrate and the third substrate.

### BACKGROUND

In electronics packaging, interconnect architectures between the board and the package substrate have been trending towards socket based solutions. In existing applications a surface mount technology (SMT) and land grid array (LGA) combination (i.e., SMT-LGA) has been used with some success. In such socketing solutions, a solder ball and a pin are provided on opposite sides of a socket substrate, and a via through the socket substrate couples the solder ball to the pin. As bandwidth and IO speed continue to increase, more pins are needed. Since there are more pins, the contact normal force for each contact will need to be reduced in order to make the socketing mechanically feasible. However, reducing the contact normal force makes the contacts more susceptible to electrical failure such as opens or high resistances.

Additionally, compression mounted technology (CMT) solutions are being proposed to further improve IO speed. So called CMT-LGA solutions replace the solder ball with an additional pin on the bottom of the socket substrate. This leads to a doubling of the number of contact interfaces. As the number of contact interfaces grows, the chance of electrical failure grows as well.

Accordingly, increasing numbers of contact interfaces coupled with a decrease in the contact normal force is potentially problematic. For example, environmental conditions (e.g., moisture, contamination, etc.) can lead to corrosion or other degradation of the contact interfaces.

### BRIEF DESCRIPTION OF THE DRAWINGS

FIG. 1A is a cross-sectional illustration of an electronic system with a socket structure that comprises a socket substrate, solder balls, and pins, in accordance with an embodiment.

FIG. 1B is a cross-sectional illustration of an electronic system with a socket structure that comprises a socket substrate, first pins, and second pins, in accordance with an embodiment.

FIG. 1C is a cross-sectional illustration of an electronic system with a socket structure that comprises a frame with a plurality of wells and liquid metal within the plurality of wells, in accordance with an embodiment.

FIG. 2A is a cross-sectional illustration of an electronic system that has an environmentally sealed socket structure with a seal ring between the heat spreader and the board, in accordance with an embodiment.

FIG. 2B is a cross-sectional illustration of an electronic system that has an environmentally sealed socket structure with a bellows ring between the heat spreader and the board, in accordance with an embodiment.

FIG. 2C is a cross-sectional illustration of an electronic system that has an environmentally sealed socket structure with a ring that is compressed between bolsters on the heat spreader and the board, in accordance with an embodiment.

FIG. 3 is a cross-sectional illustration of an electronic system with a package carrier around the package substrate, and the package carrier provides an environmental seal around the socket structure, in accordance with an embodiment.

FIG. 4A is a plan view illustration of a portion of an electronic system with a bolster that includes a seal ring around a socket structure, in accordance with an embodiment.

FIG. 4B is a cross-sectional illustration of a portion of an electronic system with a seal ring compressed between the bolster and the package carrier in order to provide an environmental seal around the socket structure, in accordance with an embodiment.

FIG. 5A is a cross-sectional illustration of an electronic system that includes a seal ring between the socket structure and the package substrate, in accordance with an embodiment.

FIG. 5B is a cross-sectional illustration of an electronic system that includes a seal ring between the socket structure and the package substrate, and a seal ring is provided between the socket structure and a bolster, in accordance with an embodiment.

FIG. 6 is a cross-sectional illustration of an electronic system that includes a bellows ring around the package substrate and the socket structure, and seal rings are provided between the socket structure and the board and the package substrate, in accordance with an embodiment.

FIG. 7 is a schematic of a computing device built in accordance with an embodiment.

### EMBODIMENTS OF THE PRESENT DISCLOSURE

Described herein are electronic systems, and more particularly, architectures with electronic packages that include socket based interconnects that are environmentally sealed, in accordance with various embodiments. In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

As noted above, existing socketing structures are trending toward an increase in pin counts and contact interfaces. The contact normal force for each of the contact interfaces is also being decreased. Increasing the number of contact interfaces provides a larger number of interconnects that could potentially fail. Further, reducing the contact normal force makes a contact interface more susceptible to degradation due to oxidation, corrosion, or other defects. These defects can lead to electrical opens, high resistances, or other negative electrical properties. Accordingly, there are more opportunities for defects, and the threshold for generating a defect is lower.

Additionally, trends towards the use of immersion cooling (e.g., including oil) induces additional requirements on socketing structures. For example, a higher dielectric constant and higher loss tangent (than air) tends to negatively impact signal integrity. This can result in signal speeds being limited. Additionally, contact interface resistance can be increased due to immersion cooling. This limits the current carrying capability. Accordingly, a sealing structure may be necessary in order to avoid interaction between the cooling fluid and the socketing structure. For simplicity in manufacturing, it may be desirable to include a sealed socketing structure for both air-cooled and immersion cooled solutions in order to avoid the need for component redesigns between product lines.

Therefore, embodiments disclosed herein aim to reduce the probability of forming defects at the contact interfaces. In some instances, this is accomplished by forming an environmentally sealed region around the socket structure. As used herein, “environmentally sealed” or an “environmental seal” may refer to a seal that substantially prevents the flow of gasses, moisture, fluids, or other contaminants into the sealed region. In some instances, an environmental seal may be a hermetic seal. The use of an environmental seal prevents moisture and the like from interacting with the contact interfaces of the socket structure. Accordingly, oxidation and/or corrosion is mitigated or completely eliminated. This improves the reliability and performance of the electronic system.

In some embodiments, the environmental seal is made by a ring or barrier that is provided between the heatsink and the board. For example, the ring may be an elastomeric material (e.g., a rubber) or the like. In other embodiments, the barrier may have a bellows type structure. The bellows may be a metallic material or the like. In some instances, the ring may directly contact the board and the heatsink. In other embodiments, the ring may be compressed between a bolster on one or both of the heatsink and the board.

In another embodiment, the environmental seal may be formed, at least in part, by a package carrier that is coupled to the package substrate. In one embodiment, the package carrier may be coupled to the package substrate by a first ring and coupled to the board by a second ring. In other embodiments, the package carrier may be pressed against a seal ring that is between the package carrier and a bolster on the board.

In yet another embodiment, the environmental seal may be provided between the socket structure and the package substrate. For example, a seal ring surrounding pins may be compressed between the package substrate and a socket substrate. Such embodiments may also comprise a seal ring between a bolster and the socket substrate in order to provide an environmental seal around the bottom interconnects as well.

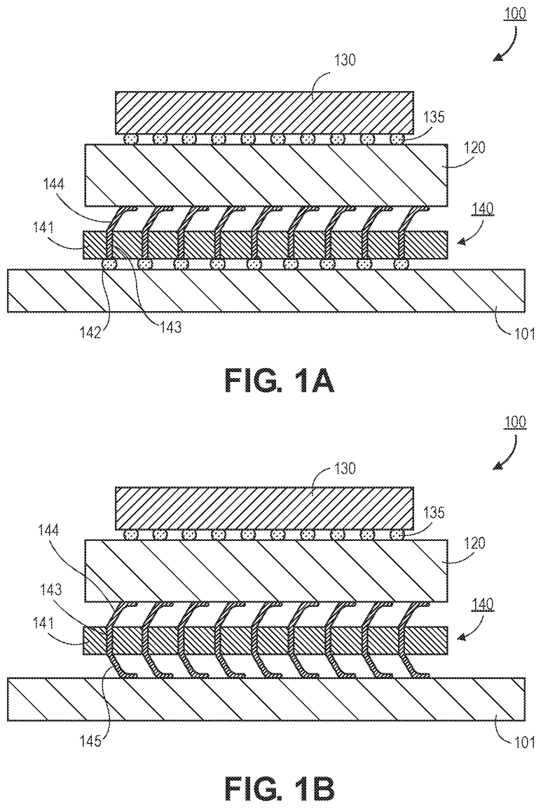

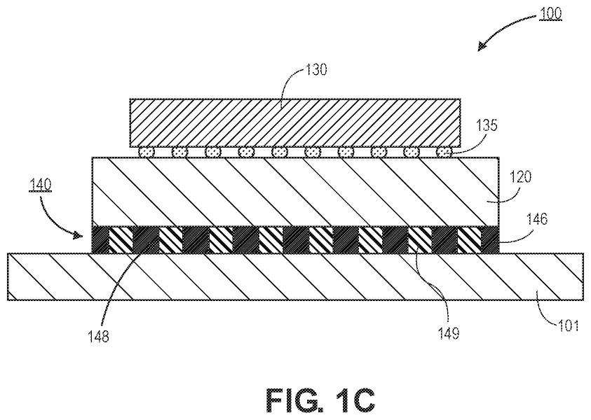

Embodiments disclosed herein may be applicable to any type of socketing structure. For simplicity, the details of the socket structure are omitted from some Figures. However, several different socket structures are illustrated in FIGS. 1A-1C for reference. The socket structures in FIGS. 1A-1C may be integrated into any of the electronic systems described in greater detail herein. That is, environmental sealing solutions described herein may work with any of the socket structures in FIGS. 1A-1C, as well as with any other socket structure that may be proposed or implemented.

Referring now to FIG. 1A, a cross-sectional illustration of an electronic system 100 is shown, in accordance with an embodiment. The electronic system 100 may comprise a board 101. The board 101 may be a printed circuit board (PCB), a motherboard, or the like. In an embodiment, a package substrate 120 is provided over the board 101. The package substrate 120 may include a core (e.g., a glass core, an organic core, or the like), with buildup layers over the core. The buildup layers may comprise laminated layers of buildup film. Electrical routing (e.g., pads, traces, vias, etc.) may be provided on and/or in the package substrate 120. Other components (e.g., passives, bridge dies, etc.) may also be embedded within portions of the package substrate 120.

In an embodiment, a die 130 is provided over the package substrate 120. The die 130 may be any type of die, such as, but not limited to, a central processing unit (CPU), a graphics processing unit (GPU), an XPU, a communications die, a memory die, an application-specific integrated circuit (ASIC), a field programmable gate array (FPGA), or the like. The die 130 may be coupled to the package substrate 120 by interconnects 135. The interconnects 135 may be any first level interconnect (FLI) architecture, such as, solder balls, copper bumps, hybrid bonding interfaces, or the like.

In an embodiment, a socket structure 140 may be provided between the board 101 and the package substrate 120. The socket structure 140 may provide electrical interconnects between the board 101 and the package substrate 120. In the particular embodiment shown in FIG. 1A, the socket structure 140 may comprise a socket substrate 141. The socket substrate 141 may be an organic dielectric material, a glass material, a semiconductor material, or any other suitable material. The socket substrate 141 may comprise a plurality of vias 143. The vias 143 may be electrically conductive structures that pass through at least a portion of the thickness of the socket substrate 141.

In an embodiment, first interconnects 142 may be provided between the board 101 and the socket substrate 141. The first interconnects 142 may comprise solder, such as a tin-based solder. Though, any suitable solder material may be used for the first interconnects 142 in other embodiments. In an embodiment, second interconnects 144 may be provided between the socket substrate 141 and the package substrate 120. The second interconnects 144 may be different than the first interconnects 142. For example, the second interconnects 144 may comprise pins or the like. In an embodiment, the pins of the second interconnects 144 may be cantilevered so that they are easier to compress against the package substrate 120. This enables better electrical connections. The first interconnects 142 may be electrically coupled to the second interconnects 144 by vias 143.

In order to compress the package substrate 120 against the socket structure 140, a retention mechanism (not shown) may be used. The retention mechanism may apply a force on the electronic system 100 so that the package substrate 120 and the board 101 compress against the socket structure 140. The retention mechanism may include clamps, screws, bolts, springs, or any other mechanism suitable to apply a compressive force on the electronic system 100.

Referring now to FIG. 1B, a cross-sectional illustration of an electronic system 100 is shown, in accordance with an additional embodiment. The electronic system 100 in FIG. 1B may be similar to the electronic system 100 in FIG. 1A with the exception of the socket structure 140. In FIG. 1A, the socket structure 140 may be referred to as being an SMT-LGA structure. However, in FIG. 1B the socket structure 140 may be referred to as being a CMT-LGA structure.

In an embodiment, the socket structure 140 may comprise a socket substrate 141. The socket substrate 141 may be an organic dielectric material, a glass material, a semiconductor material, or any other suitable material. The socket substrate 141 may comprise a plurality of vias 143. The vias 143 may be electrically conductive structures that pass through at least a portion of the thickness of the socket substrate 141.

In an embodiment, first interconnects 145 may be provided between the board 101 and the socket substrate 141. The first interconnects 145 may comprise electrically conductive pins. The pins of the first interconnects 145 may be cantilevered so that they can be more easily compressed to provide improved electrical contact with the underlying board 101. In an embodiment, second interconnects 144 may be provided between the socket substrate 141 and the package substrate 120. The second interconnects 144 may be similar to the first interconnects 145. For example, the second interconnects 144 may also comprise pins or the like. The pins of the second interconnects 144 may also be cantilevered in order to provide improved electrical connections.

The first interconnects 145 may be electrically coupled to the second interconnects 144 by vias 143. In the illustrated embodiment, the first interconnects 145 and the second interconnects 144 are mirror images of each other (across a line through the middle of the socket substrate 141). Though, embodiments are not limited to such constructions. For example, the first interconnects 145 may have a different shape, size, composition, orientation, or the like.

The use of a double pin configuration for the socket structure increases the number of contact interfaces within the electronic system 100. A contact interface may refer to the interface between the interconnects 145 or 144 and the overlying or underlying substrates (i.e., the board 101 and the package substrate 120). With an increase in the number of contact interfaces, there needs to be improved corrosion or oxidation mitigation. As will be described in greater detail below, this can be implemented through the use of environmentally sealed regions within the electronic system 100.

Referring now to FIG. 1C, a cross-sectional illustration of an electronic system 100 is shown, in accordance with an additional embodiment. The electronic system 100 in FIG. 1C may be similar to the electronic system 100 in FIG. 1A with the exception of the socket structure 140. In FIG. 1A, the socket structure 140 may be referred to as being an SMT-LGA structure. However, in FIG. 1C the socket structure 140 may be referred to as a liquid metal socket structure.

In an embodiment, the socket structure 140 may comprise a frame 146. The frame 146 may comprise a dielectric material, or any other electrically non-conductive material. In some instances, polymers, foams, or the like may be used as part of the frame 146. The frame 146 may comprise a plurality of wells 148 that pass through a thickness of the frame 146. The wells 148 may be filled with a liquid metal 149. A liquid metal 149 may refer to a material that is both electrically conductive and in the liquid phase at (or around) room temperature. For example, the liquid metal 149 may remain in the liquid phase down to approximately 0° C. or down to approximately −20° C. The liquid metal 149 may comprise any suitable metal element or alloy of elements. For example, the liquid metal 149 may comprise one or more of gallium, indium, tin, or the like.

The use of liquid metal 149 based socket structures 140 can have several benefits. One benefit is that the thickness of the socket structure 140 is reduced compared to other solutions since there are no pins extending out from the frame 146. Such socket structures 140 can also be used to reduce the contact normal force needed for the electronic system 100. This allows for liquid metal 149 based solutions to scale to higher pin counts in some embodiments. However, liquid metal 149 is also subject to corrosion and/or oxidation. As such, socket structures 140 with liquid metal 149 interconnects can also benefit from environmental sealing embodiments described in greater detail herein.

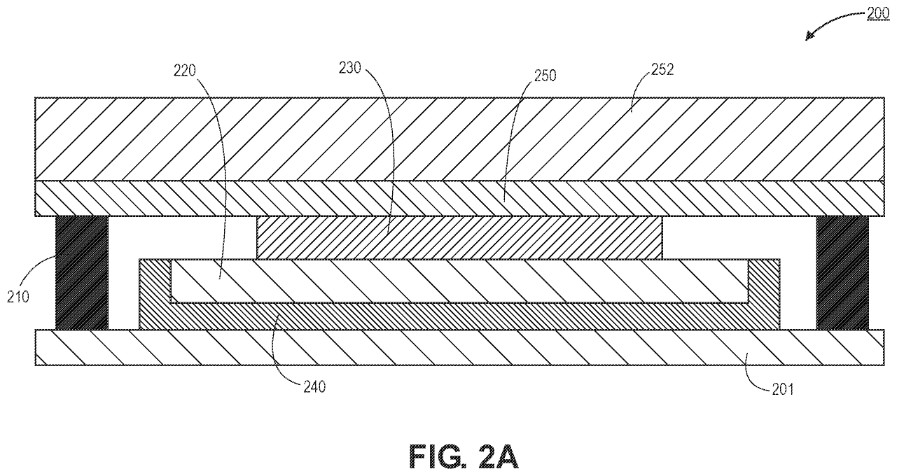

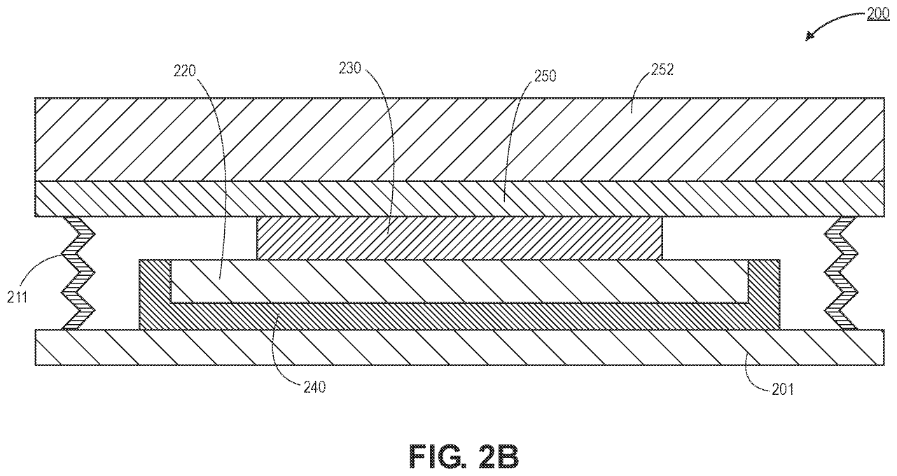

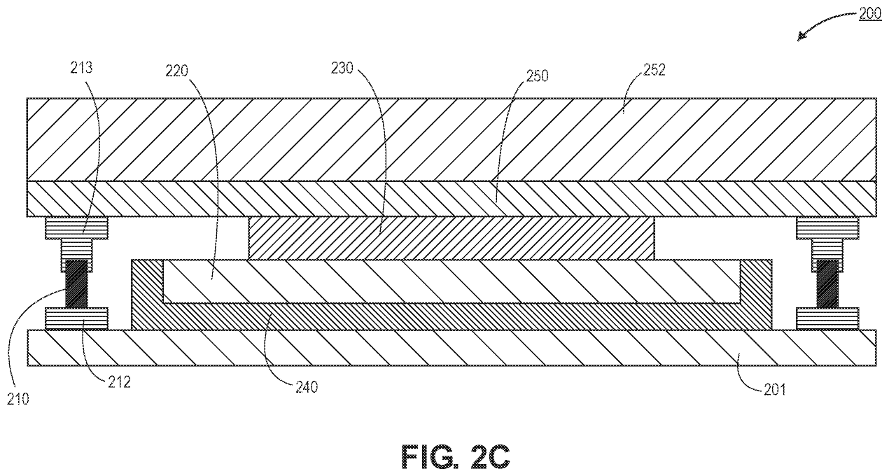

Referring now to FIG. 2A, a cross-sectional illustration of an electronic system 200 is shown, in accordance with an embodiment. In an embodiment, the electronic system 200 comprises a board 201, such as a PCB, a motherboard, or the like. In an embodiment, a package substrate 220 is provided over the board 201. The package substrate 220 may comprise a core (e.g., a glass core, an organic core, etc.) and buildup layers over and/or under the core. The buildup layers may comprise laminated buildup film layers with embedded electrically conductive routing (e.g., pads, traces, vias, etc.).

In an embodiment, a socket structure 240 is provided between the package substrate 220 and the board 201. In the illustration of FIG. 2A, the socket structure 240 directly contacts both the board 201 and the package substrate 220. However, it is to be appreciated that interconnects, such as pins, solder, liquid metal, or the like may also be provided between the board 201 and the socket structure 240, and/or between the socket structure 240 and the package substrate 220. For example, the socket structure 240 may be similar to any of the socket structures described in greater detail herein. In an embodiment, the socket structure 240 has a recess, and the package substrate 220 is set into the recess. That is, arms of the socket structure 240 may wrap up along at least a portion of the height of sidewalls of the package substrate 220.

In an embodiment, at least one die 230 is coupled to the package substrate 220. FLIs (not shown) may be provided between the die 230 and the package substrate 220 to provide electrical coupling between the two components. The die 230 may include any type of die, such as any of those described in greater detail herein.

In an embodiment, a heat sink 250 may be provided over the die 230. The heat sink 250 may be thermally coupled to the die 230 by a thermal interface material (TIM) or the like (not shown in FIG. 2A). The heat sink 250 may be a material with a high thermal conductivity in order to effectively remove heat from the die 230. For example, the heat sink 250 may comprise a metal, such as aluminum, copper, or the like. A heat spreader 252 or the like may also be provided over the heat sink 250 in some embodiments.

In an embodiment, a ring 210 may be provided around at least the socket structure 240 and the package substrate 220. The ring 210 may be mechanically coupled to the heat sink 250 and the board 201. As used herein, “mechanically coupled” may refer to components that are attached to each other and/or in contact with each other. In instances, mechanical coupling may refer to two components that are directly connected to each other and/or in contact with each other. In other instances, mechanical coupling may refer to two components that are connected to each other through the use of one or more intervening components, structures, or layers. For example, in the embodiment shown in FIG. 2A, the ring 210 directly contacts both the heat sink 250 and the board 201.

In an embodiment, the ring 210 is compressed between the heat sink 250 and the board 201. For example, a retention mechanism (not shown) may press the heat sink 250 and the board 201 together, and this causes the ring 210 to be compressed. The compressed ring 210 forms an environmentally sealed region within the electronic system 200. As shown, at least the socket structure 240 is within the environmentally sealed region. This protects the interconnects (e.g., pins, solder, liquid metal, etc.) from conditions that would otherwise lead to corrosion, oxidation, or other defects that could negatively impact electrical performance. Accordingly, reliability of the electronic system 200 is improved. Interconnects of the socket structure 240 that are above or below the socket substrate are both protected in the environmentally sealed region. In an embodiment, the ring 210 may comprise any material suitable for making such a seal, such as a polymer, an elastomeric material (e.g., rubber), or any material typically used in gasket or O-ring applications.

Referring now to FIG. 2B, a cross-sectional illustration of an electronic system 200 is shown, in accordance with an embodiment. The electronic system 200 in FIG. 2B may be similar to the electronic system 200 in FIG. 2A, with the exception of the structure used to form the environmental seal around the socket structure 240. Instead of a ring 410, a bellows 211 is provided between the heat sink 250 and the board 201. The bellows 211 may be mechanically coupled to the heat sink 250 and the board 201. In some instances, the bellows 211 directly contacts one or both of the heat sink 250 and the board 201.

The bellows 211 may have a zig-zag profile when viewed in a cross-section. The bellows 211 may be compressible or extendable. This allows for the environmental seal to be maintained despite changes to the distance between the heat sink 250 and the board 201. The bellows 211 may comprise a metallic material, such as aluminum, in some embodiments. Though any suitable metallic material may be used.

In an embodiment, the bellows 211 forms a ring that surrounds at least the socket structure 240. In FIG. 2B, the bellows 211 also surrounds the package substrate 220 and the die 230. As such, the package substrate 220, the die 230, and the socket structure 240 are provided within the environmentally sealed region of the electronic system 200. More particularly, the environmentally sealed region protects interconnects of the socket structure 240 that are coupled to either the board 201 or the package substrate 220 (i.e., interconnects above and below a socket substrate).

Referring now to FIG. 2C, a cross-sectional illustration of an electronic system 200 is shown, in accordance with an additional embodiment. As shown, the electronic system 200 in FIG. 2C is similar to the electronic system 200 in FIG. 2A, with the exception of the formation of the environmental seal. Instead of having a ring 210 that contacts the heat sink 250 and the board 201, the ring 210 in FIG. 2C is compressed between bolsters 212 and 213.

In an embodiment, a first bolster 212 is provided over the surface of the board 201. The first bolster 212 may be a frame-like structure that surrounds the socket structure 240. The first bolster 212 may comprise any material. In some embodiments, the first bolster 212 comprises aluminum or another metallic material. The first bolster 212 may have a rectangular cross-section along each side of the socket structure 240. Though, any cross-section may be used for the first bolster 212.

In an embodiment, a second bolster 213 is provided over the surface of the heat sink 250. The second bolster 213 may be a frame-like structure that surrounds the die 230. The second bolster 213 may comprise any material. In some embodiments, the second bolster 213 comprises aluminum or another metallic material. The second bolster 213 may have a T-shaped cross-section along each side of the die 230. Though, any cross-section may be used for the second bolster 213.

In an embodiment, the ring 210 is provided between the first bolster 212 and the second bolster 213. In some instances, the ring 210 is pressed against a flat surface of the first bolster 212, and the ring 210 is inserted into a channel in the second bolster 213. Though, it is to be appreciated that any retention or coupling structures may be used to secure the ring 210 in place. In an embodiment, the ring 210 may comprise any material suitable for making such a seal, such as a polymer, an elastomeric material (e.g., rubber), or any material typically used in gasket or O-ring applications.

In an embodiment, the combination of the first bolster 212, the ring 210, and the second bolster 213 forms a ring that surrounds at least the socket structure 240. In FIG. 2C, the sealing structure (i.e., 212, 210, 213) also surrounds the package substrate 220 and the die 230. As such, the package substrate 220, the die 230, and the socket structure 240 are provided within the environmentally sealed region of the electronic system 200. More particularly, the environmentally sealed region protects interconnects of the socket structure 240 that are coupled to the board 201 or to the package substrate 220 (i.e., interconnects above and below a socket substrate).

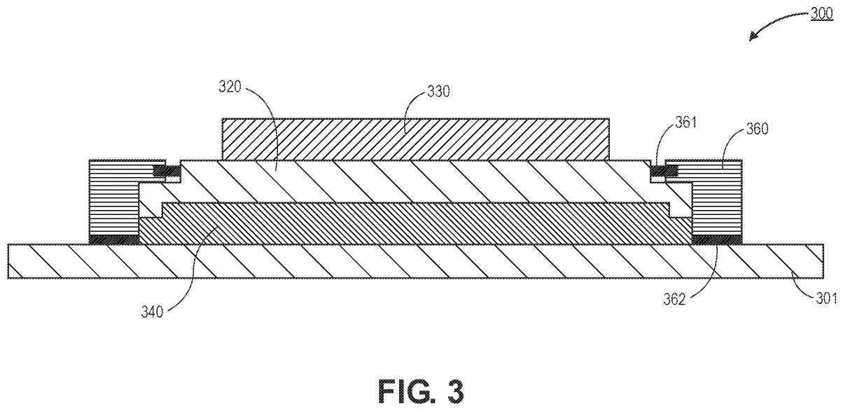

Referring now to FIG. 3, a cross-sectional illustration of an electronic system 300 is shown, in accordance with an additional embodiment. The electronic system 300 may comprise a board 301 similar to any of the boards described in greater detail herein. A package substrate 320 may be provided over the board 301. The package substrate 320 may be similar to any of the package substrates described in greater detail herein.

In an embodiment, a socket structure 340 is provided between the package substrate 320 and the board 301. In the illustration of FIG. 3, the socket structure 340 directly contacts both the board 301 and the package substrate 320. However, it is to be appreciated that interconnects, such as pins, solder, liquid metal, or the like may also be provided between the board 301 and the socket structure 340, and/or between the socket structure 340 and the package substrate 320. For example, the socket structure 340 may be similar to any of the socket structures described in greater detail herein. In an embodiment, the socket structure 340 and the package substrate 320 have an interlocking portion around a perimeter of both structures. In some instances, the interlocking features contact each other, and in other instances the interlocking features are spaced apart from each other. In an embodiment, one or more dies 330 are provided over the package substrate 320. The die 330 may be electrically coupled to the package substrate 320 by any suitable interconnect architecture, such as FLI architectures (not shown).

In an embodiment, the package substrate 320 may be retained by a package carrier or frame 360 that surrounds a perimeter of the package substrate 320. The frame 360 may be a metallic material, such as aluminum, or any other suitable rigid material. In some embodiments, the frame 360 covers at least a portion of the sidewall surface of the package substrate 320. Further, the frame 360 may extend down along sidewalls of the socket structure 340. In an embodiment, the frame 360 is mechanically coupled to the board 301 by a bolt, clip, or any other suitable retention mechanism (not shown).

The environmental seal around the socket structure 340 is provided by one or more rings 361 and 362. The first ring 361 may be compressed between the package substrate 320 and the frame 360. The second ring 362 may be compressed between the frame 360 and the board 301. In an embodiment, the rings 361 and 362 may comprise any material suitable for making such a seal, such as a polymer, an elastomeric material (e.g., rubber), or any material typically used in gasket or O-ring applications.

In an embodiment, the combination of the rings 361 and 362 with the frame 360 forms an environmental seal around at least the socket structure 240. In FIG. 3, the sealing structure (i.e., 360, 361, and 362) also surrounds at least a portion of the package substrate 320. As such, at least a portion of the package substrate 320 and the socket structure 340 are provided within the environmentally sealed region of the electronic system 300. More particularly, the environmentally sealed region protects interconnects of the socket structure 340 that are coupled to the board 301 or the package substrate 320 (i.e., interconnects above and below a socket substrate).

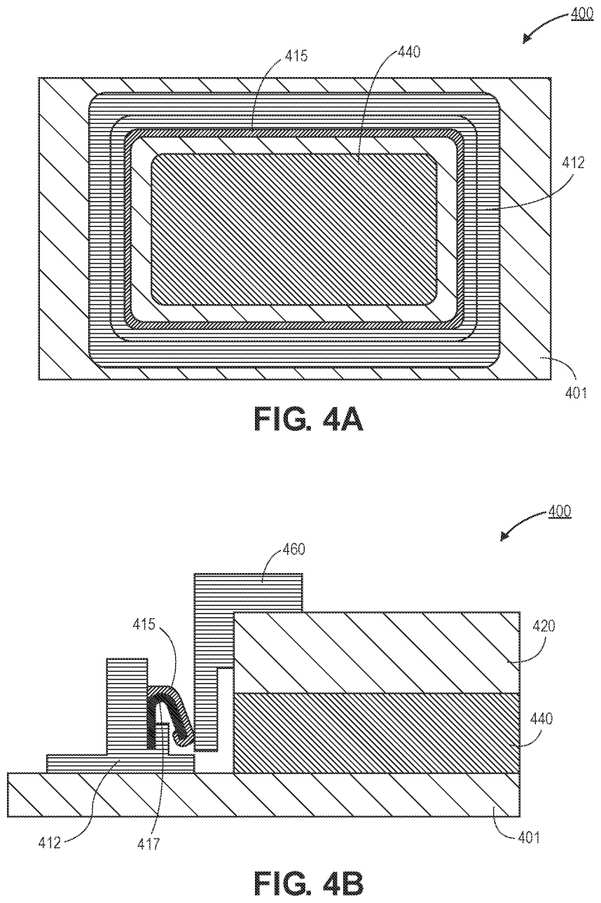

Referring now to FIG. 4A, a plan view illustration of a portion of an electronic system 400 is shown, in accordance with an embodiment. The electronic system 400 may comprise a board 401. The board 401 may be similar to any of the boards described in greater detail herein. In an embodiment, a bolster 412 may be provided over the board 401. The bolster 412 may be a frame-like structure. The bolster 412 may comprise a metal (e.g., aluminum) or any other suitable rigid material. A ring 415 may be provided along an interior surface of the bolster 412. The ring 415 may be a compressible material suitable for making an environmental seal, as will be described in greater detail below. For example, the ring 415 may comprise any material suitable for making such a seal, such as a polymer, an elastomeric material (e.g., rubber), or any material typically used in gasket or O-ring applications. In an embodiment, a socket structure 440 may be surrounded by the bolster 412. The socket structure 440 may be similar to any of the socket structures described in greater detail herein.

Referring now to FIG. 4B, a cross-sectional illustration of a portion of the electronic system 400 is shown, in accordance with an embodiment. As shown, a package substrate 420 is provided over the socket structure 440. The package substrate 420 may be similar to any of the package substrates described in greater detail herein. In an embodiment, a frame 460 may be mechanically coupled to the package substrate 420. In an embodiment, the frame 460 may have an extension that extends down a sidewall of the package substrate 420 and at least partially over a sidewall of the socket structure 440.

In an embodiment, the frame 460 presses up against the ring 415. The ring 415 may be provided over a mechanical support 417 that extends up from the bolster 412. The frame 460 presses against the ring 415 in order to make an environmental seal. In an embodiment, the combination of the frame 460 with the ring 415 forms an environmental seal around at least the socket structure 440. In FIG. 4B, the sealing structure (i.e., 460 and 415) also surrounds at least a portion of the package substrate 420. As such, at least a portion of the package substrate 420 and the socket structure 440 are provided within the environmentally sealed region of the electronic system 400. More particularly, the environmentally sealed region protects interconnects of the socket structure 440 that are coupled to the board 401 or the package substrate 420 (i.e., interconnects above and below a socket substrate).

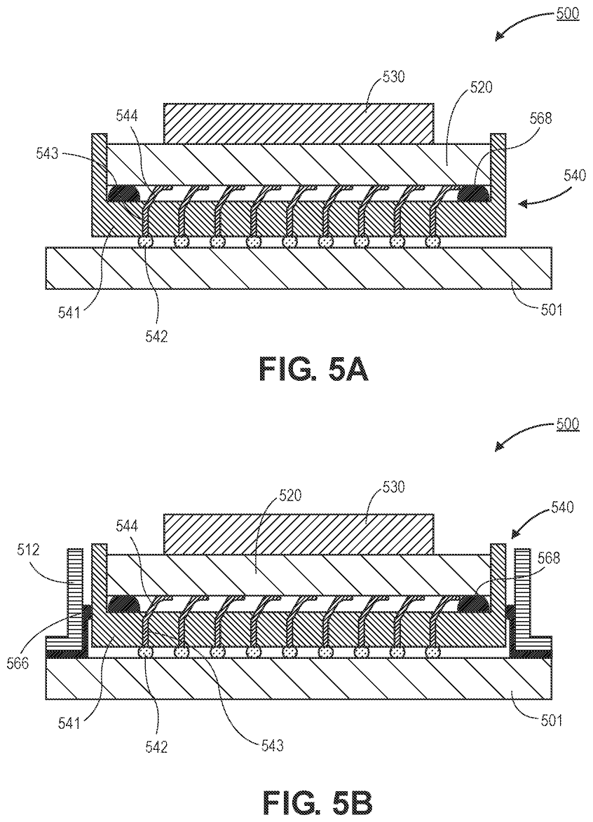

Referring now to FIG. 5A, a cross-sectional illustration of an electronic system 500 is shown, in accordance with an embodiment. The electronic system 500 comprises a board 501 that may be similar to any of the boards described in greater detail herein. In an embodiment, a package substrate 520 may be provided over the board 501. The package substrate 520 may be similar to any of the package substrates described in greater detail herein. In an embodiment, one or more dies 530 are coupled to the package substrate 520 by interconnects (not shown), such as any FLI architecture. The die 530 may be similar to any die described in greater detail herein.

In an embodiment, a socket structure 540 may be provided between the board 501 and the package substrate 520. The socket structure 540 may comprise a substrate 541 with interconnects coupling the board 501 to the package substrate 520. For example, first interconnects 542 are on the board 501 and second interconnects 544 are on the package substrate 520. Vias 543 through the substrate 541 couple first interconnects 542 to second interconnects 544. In the illustrated embodiment, the first interconnects 542 are solder balls and the second interconnects 544 are cantilevered pins. Though, any interconnect architecture for socket structures described in greater detail herein may be used in some embodiments.

In an embodiment, a ring 568 may be provided between the substrate 541 and the package substrate 520. The ring 568 may surround a perimeter of the array of second interconnects 544. The ring 568 may be compressed between the substrate 541 and the package substrate 520 in order to form an environmental seal that protects the second interconnects 544. The ring 568 may comprise any material suitable for making such a seal, such as a polymer, an elastomeric material (e.g., rubber), or any material typically used in gasket or O-ring applications.

Referring now to FIG. 5B, a cross-sectional illustration of an electronic system 500 is shown, in accordance with an additional embodiment. The electronic system 500 in FIG. 5B may be similar to the electronic system 500 in FIG. 5A, with the addition of a bolster 512 on the board 501. The bolster 512 and an edge of the socket structure 540 may compress a second ring 566. The second ring 566 may also include a portion that extends between the bolster 512 and the board 501. Though, two separate ring structures may be used (i.e., one for between the socket structure 540 and the bolster 512, and a second one for between the bolster 512 and the board 501). Accordingly, a second environmentally sealed region is provided below the substrate 541 in order to protect the first interconnects 542.

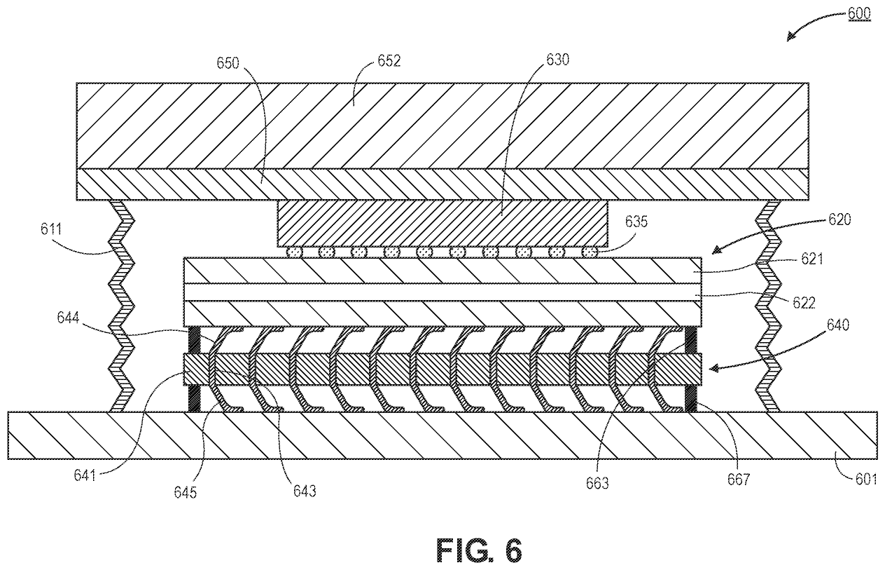

Referring now to FIG. 6, a cross-sectional illustration of an electronic system 600 is shown, in accordance with an embodiment. In an embodiment, the electronic system 600 may comprise a board 601, a package substrate 620, and one or more dies 630. The board 601 may be similar to any of the boards described in greater detail herein. The package substrate 620 may be similar to any of the package substrates described in greater detail herein. For example, the package substrate 620 may comprise a core 622 (e.g., a glass core or an organic core), and buildup layers 621 above and below the core 622. The die 630 may be similar to any of the dies described in greater detail herein. The die 630 may be coupled to the package substrate 620 by interconnects 635. In an embodiment, a heat sink 650 and a heat spreader 652 may be provided over the die 630.

In an embodiment, a socket structure 640 may be provided between the board 601 and the package substrate 620. The socket structure 640 may be similar to any of the socket structures described in greater detail herein. For example, the socket structure 640 may comprise a substrate 641 with first interconnects 645 below the substrate 641 and second interconnects 644 over the substrate 641. Vias 643 may couple the first interconnects 645 to the second interconnects 644. While shown as pins, it is to be appreciated that the interconnects 645 and 644 may include any suitable interconnect architecture.

In an embodiment, bellows 611 may be provided between the heat sink 650 and the board 601. The bellows 611 may provide a first environmentally sealed region of the electronic system 600. The first environmentally sealed region includes the die 630, the package substrate 620, and the socket structure 640. While bellows 611 are shown, other sealing structures (e.g., an elastomeric ring or any other structure described in greater detail herein) may be provided between the heat sink 650 and the board 601 to form the first environmentally sealed region.

In an embodiment, a first ring 667 may be provided around the first interconnects 645 to form a second environmentally sealed region. The first ring 667 may be compressed between the board 601 and the substrate 641. In an embodiment, a second ring 663 may be provided around the second interconnects 644 to form a third environmentally sealed region. The second ring 663 may be compressed between the package substrate 620 and the substrate 641. In an embodiment, the first ring 667 and the second ring 663 may comprise any material suitable for making such a seal, such as a polymer, an elastomeric material (e.g., rubber), or any material typically used in gasket or O-ring applications.

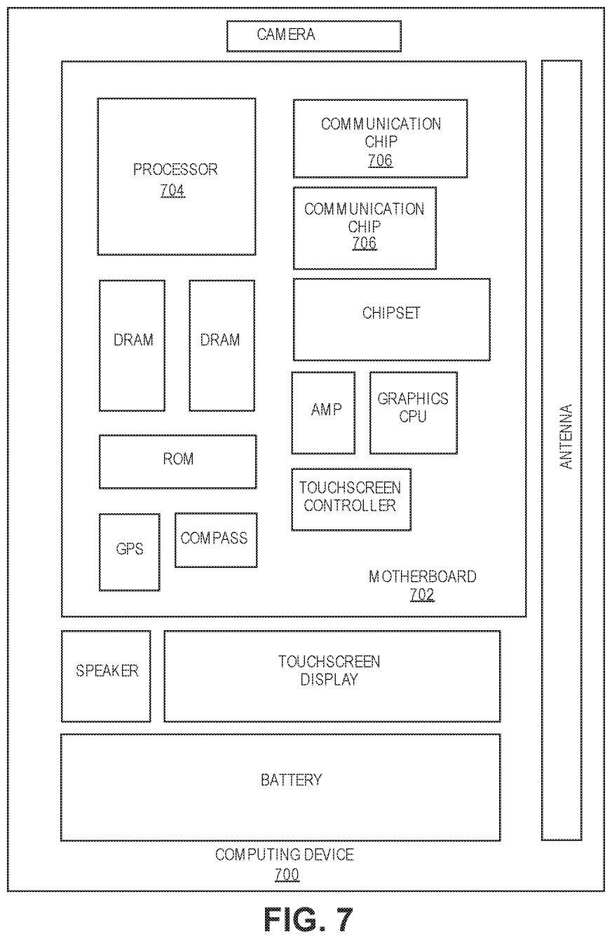

FIG. 7 illustrates a computing device 700 in accordance with one implementation of the disclosure. The computing device 700 houses a board 702. The board 702 may include a number of components, including but not limited to a processor 704 and at least one communication chip 706. The processor 704 is physically and electrically coupled to the board 702. In some implementations the at least one communication chip 706 is also physically and electrically coupled to the board 702. In further implementations, the communication chip 706 is part of the processor 704.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 706 enables wireless communications for the transfer of data to and from the computing device 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 706 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 700 may include a plurality of communication chips 706. For instance, a first communication chip 706 may be dedicated to shorter range wireless communications such as Wi-Fi and Bluetooth and a second communication chip 706 may be dedicated to longer range wireless communications such as GPS, EDGE, GPRS, CDMA, WiMAX, LTE, Ev-DO, and others.

The processor 704 of the computing device 700 includes an integrated circuit die packaged within the processor 704. In some implementations of the disclosure, the integrated circuit die of the processor may be part of an electronic package that includes a socket structure that is within an environmentally sealed region, in accordance with embodiments described herein. The term “processor” may refer to any device or portion of a device that processes electronic data from registers and/or memory to transform that electronic data into other electronic data that may be stored in registers and/or memory.

The communication chip 706 also includes an integrated circuit die packaged within the communication chip 706. In accordance with another implementation of the disclosure, the integrated circuit die of the communication chip may be part of an electronic package that includes a socket structure that is within an environmentally sealed region, in accordance with embodiments described herein.

In an embodiment, the computing device 700 may be part of any apparatus. For example, the computing device may be part of a personal computer, a server, a mobile device, a tablet, an automobile, or the like. That is, the computing device 700 is not limited to being used for any particular type of system, and the computing device 700 may be included in any apparatus that may benefit from computing functionality.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

Example 1: an apparatus, comprising: a first substrate; a second substrate over the first substrate; a socket structure between the first substrate and the second substrate, wherein the socket structure comprises a plurality of electrical interconnects between the first substrate and the second substrate; a die over the second substrate; a third substrate over the die; and a ring around the socket structure, wherein the ring is coupled to the first substrate and the third substrate.

Example 2: the apparatus of Example 1, wherein the ring comprises an elastomeric material.

Example 3: the apparatus of Example 1 or Example 2, wherein the ring comprises a bellows structure.

Example 4: the apparatus of Examples 1-3, further comprising: a first bolster on the first substrate; and a second bolster on the third substrate, and wherein the ring is coupled to the first substrate through the first bolster and coupled to the third substrate through the second bolster.

Example 5: the apparatus of Examples 1-4, wherein the third substrate is a heat sink.

Example 6: the apparatus of Examples 1-5, wherein the socket structure comprises: a socket substrate; a plurality of first pins between the socket substrate and the first substrate; and a plurality of second pins between the socket substrate and the second substrate.

Example 7: the apparatus of Examples 1-6, wherein the socket structure comprises: a socket substrate; a plurality of solder bumps between the first substrate and the socket substrate; and a plurality of pins between the socket substrate and the second substrate.

Example 8: the apparatus of Examples 1-7, wherein the socket structure comprises: a frame with a plurality of wells; and liquid metal within the plurality of wells.

Example 9: an apparatus, comprising: a first substrate; a second substrate over the first substrate; a socket structure between the first substrate and the second substrate, wherein the socket structure comprises a plurality of electrical interconnects between the first substrate and the second substrate; and a frame around the second substrate.

Example 10: the apparatus of Example 9, further comprising: a ring between the frame and the second substrate.

Example 11: the apparatus of Example 9 or Example 10, further comprising: a ring between the frame and the first substrate.

Example 12: the apparatus of Examples 9-11, further comprising: a bolster on the first substrate; and a ring between the bolster and the frame.

Example 13: the apparatus of Examples 9-12, wherein the frame contacts a surface of the second substrate that faces away from the first substrate.

Example 14: the apparatus of Examples 9-13, wherein the electrical interconnects comprise a plurality of pins or a plurality of liquid metal wells.

Example 15: an apparatus, comprising: a first substrate; a second substrate over the first substrate; a socket structure between the first substrate and the second substrate, wherein the socket structure comprises a plurality of electrical interconnects between the first substrate and the second substrate; and a ring between the socket structure and the second substrate, wherein the ring surrounds the plurality of electrical interconnects.

Example 16: the apparatus of Example 15, wherein the plurality of interconnects surrounded by the ring are pins.

Example 17: the apparatus of Example 15 or Example 16, wherein the ring comprises an elastomeric material.

Example 18: the apparatus of Examples 15-17, wherein the socket structure comprises a recess, and wherein the second substrate is positioned within the recess.

Example 19: the apparatus of Examples 15-18, further comprising: a bolster around the socket structure; and a seal between the bolster and the socket structure, wherein the seal is configured to prevent external liquid from reaching the socket structure.

Example 20: the apparatus of Examples 15-19, wherein the apparatus is part of a personal computer, a server, a mobile device, a tablet, or an automobile.

What is claimed is:

1. An apparatus, comprising:
a first substrate;
a second substrate over the first substrate;
a socket structure between the first substrate and the second substrate, wherein the socket structure comprises a plurality of electrical interconnects between the first substrate and the second substrate;
a die over the second substrate;
a third substrate over the die; and
a ring around the socket structure, wherein the ring is coupled to the first substrate and the third substrate.

2. The apparatus of claim 1, wherein the ring comprises an elastomeric material.

3. The apparatus of claim 1, wherein the ring comprises a bellows structure.

4. The apparatus of claim 1, further comprising:
a first bolster on the first substrate; and
a second bolster on the third substrate, and wherein the ring is coupled to the first substrate through the first bolster and coupled to the third substrate through the second bolster.

5. The apparatus of claim 1, wherein the third substrate is a heat sink.

6. The apparatus of claim 1, wherein the socket structure comprises:
a socket substrate;
a plurality of first pins between the socket substrate and the first substrate; and
a plurality of second pins between the socket substrate and the second substrate.

7. The apparatus of claim 1, wherein the socket structure comprises:
a socket substrate;
a plurality of solder bumps between the first substrate and the socket substrate; and
a plurality of pins between the socket substrate and the second substrate.

8. The apparatus of claim 1, wherein the socket structure comprises:
a frame with a plurality of wells; and
liquid metal within the plurality of wells.

9. An apparatus, comprising:
a first substrate;
a second substrate over the first substrate;
a socket structure between the first substrate and the second substrate, wherein the socket structure comprises a plurality of electrical interconnects between the first substrate and the second substrate; and
a frame around the second substrate.

10. The apparatus of claim 9, further comprising:
a ring between the frame and the second substrate.

11. The apparatus of claim 9, further comprising:
a ring between the frame and the first substrate.

12. The apparatus of claim 9, further comprising:
a bolster on the first substrate; and
a ring between the bolster and the frame.

13. The apparatus of claim 9, wherein the frame contacts a surface of the second substrate that faces away from the first substrate.

14. The apparatus of claim 9, wherein the electrical interconnects comprise a plurality of pins or a plurality of liquid metal wells.

15. An apparatus, comprising:
a first substrate;
a second substrate over the first substrate;
a socket structure between the first substrate and the second substrate, wherein the socket structure comprises a plurality of electrical interconnects between the first substrate and the second substrate; and
a ring between the socket structure and the second substrate, wherein the ring surrounds the plurality of electrical interconnects.

16. The apparatus of claim 15, wherein the plurality of interconnects surrounded by the ring are pins.

17. The apparatus of claim 15, wherein the ring comprises an elastomeric material.

18. The apparatus of claim 15, wherein the socket structure comprises a recess, and wherein the second substrate is positioned within the recess.

19. The apparatus of claim 15, further comprising:
a bolster around the socket structure; and
a seal between the bolster and the socket structure, wherein the seal is configured to prevent external liquid from reaching the socket structure.

20. The apparatus of claim 15, wherein the apparatus is part of a personal computer, a server, a mobile device, a tablet, or an automobile.
